(19) United States
(12) Patent Application Publication
(10) Pub. No.: US 2025/0346810 A1
(43) Pub. Date: Nov. 13, 2025

(54) LUMINOPHORE, METHOD FOR PRODUCTION THEREOF AND RADIATION-EMITTING COMPONENT

(71) Applicant: AMS-OSRAM International GMBH, Regensburg (DE)

(72) Inventors: Johanna STRUBE-KNYRIM, Weil (DE); Gina Maya ACHRAINER, Greifenberg (DE); Daniel BICHLER, Augsburg (DE)

(21) Appl. No.: 18/866,563

(22) PCT Filed: Jun. 7, 2023
(86) PCT No.: PCT/EP2023/065195

§ 371 Date: Nov. 18, 2024

(30) Foreign Application Priority Data
Jun. 29, 2022 (DE) 102022116190.0

(51) Int. Cl. C09K 11/77; H10H 20/851

(52) U.S. Cl. CPC C09K 11/77747; H10H 20/8512

(57) ABSTRACT

A phosphor with the molecular formula EA₃₋ₓREₓD_{2+y}E_{12-y}N_{20-z}O_{z}:M is specified, where EA is an element or a combination of elements from the group of divalent elements, RE is a rare earth element, D is an element or a combination of elements from the group of trivalent elements, E is an element or a combination of elements from the group of tetravalent elements, M is an activator element or a combination of activator elements, 0≤x≤3, 0≤y≤12 and z=y−x, wherein z≥0. Further, a method for producing a phosphor and a radiation emitting component are specified.

### RELATED APPLICATIONS

This patent application is a US National Stage application, filed under 35 U.S.C. § 371, of International Application PCT/EP2023/065195, filed on Jun. 7, 2023, and claims priority under from German Patent Application No. 10 2022 116 190.0, filed Jun. 29, 2022, the contents of the above applications are hereby incorporated by reference.

### FIELD

The present disclosure relates to phosphor, a method for producing phosphor and a radiation emitting component.

### SUMMARY

Various embodiments of the present disclosure relate to a phosphor with increased efficiency. Furthermore, various embodiments relate to a method for producing such a phosphor and an improved radiation emitting component.

According to an embodiment, the phosphor comprises the molecular formula EA₃₋ₓREₓD_{2+y}E_{12-y}N_{20-z}O_{z}:M.

It is possible for the phosphor to comprise further elements, for example in the form of impurities, with the given molecular formulae. In particular, these impurities comprise at most 5 mol %, in particular at most 1 mol %, for example, at most 0.1 mol %.

According to an embodiment of the phosphor, EA is an element or a combination of elements from the group of divalent elements. In particular, EA is an element or a combination of elements selected from the group formed by Ca, Sr, and Ba.

According to an embodiment of the phosphor, RE is a rare earth element. Rare earth elements in the present case comprise the chemical elements of the 3rd subgroup of the periodic table as well as the lanthanides. RE is, for example, selected from the group formed by Sc, Y, La, Ce, Pr, Nd, Sm, Eu, Gd, Tb, Dy, Ho, Er, Tm, Yb, Lu.

According to an embodiment of the phosphor, D is an element or a combination of elements from the group of trivalent elements. In particular, D is an element or a combination of elements selected from the group formed by Al and Ga.

According to an embodiment of the phosphor, E is an element or a combination of elements from the group of tetravalent elements. In particular, E is Si.

According to an embodiment of the phosphor, M is an activator element or a combination of activator elements. In particular, M is an element or a combination of elements selected from the group formed by Ce and Eu. In particular, Ce is present in the form Ce³⁺, whereas Eu is generally present in the form Eu²⁺.

In at least one example, the phosphor comprises a host lattice into which foreign elements are introduced as the activator elements. The host lattice changes the electronic structure of the activator element in such a way that electromagnetic radiation of an excitation wavelength absorbed by the phosphor causes an electronic transition from a ground state to an excited state in the phosphor. By emitting electromagnetic radiation with an emission spectrum, the phosphor returns to the ground state.

For example, phosphors with Eu²⁺ as an activator element comprise quenching effects even at low irradiance levels of around 100 mW/mm². Phosphors with Ce³⁺ as the activator element, on the other hand, comprise in particular lower quenching effects, even at higher irradiance levels. For example, Y₃Al₅O₁₂:Ce³⁺ only exhibits quenching effects above 10 W/mm², i.e. more than an order of magnitude above the irradiance levels at which Eu²⁺ activated phosphors comprise quenching effects. This can be attributed, for example, to a lower lifetime of an excited state. The lifetime of an excited state of Ce³⁺ can be less than 100 nanoseconds, whereas an excited state of Eu²⁺ can comprise a lifetime in the region of 1 microsecond to 10 microseconds.

According to an embodiment of the phosphor, 0≤x≤3, 0≤y≤12 and z=y−x applies, wherein z≥0. In particular, y=x and thus z=0 applies.

According to an embodiment, the phosphor has the molecular formula EA₃₋ₓREₓD_{2+y}E_{12-y}N_{20-z}O_{z}:M, wherein EA is an element or a combination of elements from the group of divalent elements, RE is a rare earth element, D is an element or a combination of elements from the group of trivalent elements, E is an element or a combination of elements from the group of tetravalent elements, M is an activator element or a combination of activator elements, 0≤x≤3, 0≤y≤12 and z=y−x, wherein z≥0.

According to an embodiment of the phosphor, M comprises a molecular proportion between and including 0.1% and 10%, in particular between and including 0.1% and 5%, relative to RE and EA. In other words, between and including 0.1% and 10% of the point locations of RE and/or EA are occupied with M.

According to an embodiment, the phosphor comprises the molecular formula Ba₃₋ₓLaₓAl₂₊ₓSi₁₂₋ₓN₂₀:Ce³⁺. In this embodiment, in the empirical formula EA₃₋ₓREₓD_{2+y}E_{12-y}N_{20-z}O_{z}:M x=y and thus z=0 applies.

According to an embodiment, after excitation with electromagnetic radiation in the ultraviolet to blue wavelength range, the phosphor emits electromagnetic radiation with an emission spectrum comprising an emission peak with an emission maximum in the cyan wavelength range. In particular, it is possible to excite the phosphor with electromagnetic radiation in the ultraviolet wavelength range, for example in the wavelength range of between and including 380 nanometers and 430 nanometers. For example, the phosphor is excited with electromagnetic radiation with a wavelength of about 408 nanometers. In at least one example, the phosphor emits electromagnetic radiation with an emission maximum in the wavelength range of between and including 450 nanometers and 520 nanometers, in particular of between and including 460 nanometers and 500 nanometers. A position of the emission maximum is dependent on a composition of the phosphor.

The phosphor described herein can advantageously be used in human-centric lighting applications. Human-centric lighting refers to human-centered lighting concepts that take into account not only the purely visual but also non-visual effects of light, such as increased attention and alertness. These effects are attributed to an activation of the photoreceptor melanopsin in the eye. The ability of electromagnetic radiation to stimulate the photoreceptor melanopsin can be assessed, for example, with the “melanopic efficacy of luminous radiation” (short: melanopic ELR). In particular, the present phosphor outperforms a conventional phosphor in the melanopic ELR many times over.

According to an embodiment of the phosphor, the emission peak comprises a full-width at half maximum (FWHM) in the region of between and including 80 nanometers and 110 nanometers, in particular in the region of between and including 85 nanometers and 100 nanometers. For example, the emission peak comprises a full-width at half maximum of about 92 nanometers.

According to an embodiment of the phosphor, electromagnetic radiation emitted by the phosphor comprises a dominant wavelength λ_{dom} in the region of between and including 460 nanometers and 510 nanometers, in particular in the region of between and including 470 nanometers and 500 nanometers, for example of between and including 480 nanometers and495 nanometers. The electromagnetic radiation emitted by the phosphor comprises, for example, a dominant wavelength of about 488 nanometers.

Phosphors such as (Sr, Ba) Si₂O₂N₂:Eu²⁺ or β-SiAlON:Eu²⁺, which comprise Eu²⁺ as an activator element and an emission peak in the blue to green wavelength range, can often only be used at low irradiance levels. For example, with β-SiAlON:Eu²⁺ a maximum emission power is already achieved at around 0.7 W/mm-irradiance due to saturation effects and quenching effects. Ce³⁺-activated phosphors, such as Lu₃(Al, Ga)₅O₁₂:Ce³⁺ with emission in the cyan to green wavelength range comprise a dominant wavelength in the region of 550 nanometers to 570 nanometers and a full-width at half maximum between 100 nanometers and 120 nanometers. The exact optical properties of Lu₃(Al, Ga)₅O₁₂:Ce³⁺ depend in particular on a composition, for example a Ga content, a degree of doping and a grain size. However, with the phosphor described herein, dominant wavelengths of less than 550 nanometers can be achieved even at high irradiance levels.

According to an embodiment, the host lattice of the phosphor crystallizes in a trigonal space group, for example in the space group R3̅.

According to an embodiment of the phosphor, a crystal structure of the host lattice of the phosphor comprises D(N, O)₄ tetrahedra and/or E(N, O)₄ tetrahedra. The D(N, O)₄ tetrahedra and/or E(N, O)₄ tetrahedra are corner-linked on all sides. In particular, a tetrahedron is spanned by a total of four N and O atoms. If the atoms at the corners of the tetrahedrons are thought of as touching spheres, a tetrahedron gap forms in the middle. The tetrahedron gap is occupied by a D atom or an E atom. In other words, there is a D atom or an E atom in the center of the tetrahedron. Corner-linked on all sides means that each tetrahedron is linked to one corner of another tetrahedron via all four corners.

According to an embodiment, the crystal structure of the host lattice of the phosphor comprises layers with on all side corner-linked D(N, O)₄ tetrahedra and/or E(N, O)₄ tetrahedra. In particular, the crystal structure comprises three symmetrically different layers, each of which is extended along the crystallographic a- and b-axis, for example. In at least one example, a first layer comprises six-membered rings, a second layer comprises three-membered rings and/or a third layer comprises six-membered rings, each of the D(N, O)₄ tetrahedra and/or E(N, O)₄ tetrahedra. Within a layer, the D(N, O)₄ tetrahedra and/or E(N, O)₄ tetrahedra are, for example, linked via three of their corners. A link to another layer is established via the fourth corner. The corner of a D(N, O)₄ tetrahedron and/or E(N, O)₄ tetrahedron, which is not used for linking within a layer, points in particular in the direction of the crystallographic c-axis.

In particular, the first layer, the second layer and the third layer form a layer stack. Such a layer stack is, for example, linked with another, inversion-symmetrically arranged layer stack. This results, for example, in a layer packet comprising a total of six layers. In at least one example, the layers in the layer packet comprise the following sequence: first layer, second layer, third layer, inversion-symmetrical third layer, inversion-symmetrical second layer, inversion-symmetrical first layer.

According to an embodiment of the phosphor, EA and RE are arranged between the layers. In particular, EA and RE occupy crystallographic locations within and/or between the layer packets. In at least one example, the crystal structure of the host structure of the phosphor comprises two different crystallographic locations for EA and RE. At least one of the two different crystallographic locations, for example both, can be occupied with a mixture of EA and RE.

A method for producing a phosphor is further specified. For example, the phosphor according to the embodiments mentioned above is produced with the method described herein. In particular, all the explanations given for the phosphor also apply to the method and vice versa.

According to an embodiment, the method for producing a phosphor comprises the steps of providing reactants, mixing the reactants to form a reactant mixture and heating the reactant mixture. The phosphor comprises the molecular formula EA₃₋ₓREₓD_{2+y}E_{12-y}N_{20-z}O_{z}:M, wherein EA is an element or a combination of elements from the group of divalent elements, RE is a rare earth element, D is an element or a combination of elements from the group of trivalent elements, E is an element or a combination of elements from the group of tetravalent elements, M is an activator element or a combination of activator elements, 0≤x≤3, 0≤y≤12 and z=y−x, wherein z≥0.

In particular, it is possible for the method to produce a mixture comprising or consisting of the phosphor. Other components of the mixture may be, for example, reactants which have not reacted during the production of the phosphor, impurities and/or secondary phases which were formed during the production.

According to an embodiment of the method, the reactants are selected from a group comprising the oxides, nitrides, fluorides, oxalates, citrates, carbonates, amines, and imides of RE, EA, D, E and M.

According to an embodiment of the method, the reactant mixture is heated to a temperature in the range of between and including 1000° C. and 2000° C., in particular to a temperature in the range of between and including 1500° C. and 2000° C., for example, between and including 1800° C. and 1900° C.

According to an embodiment of the method, the heating of the reactant mixture takes place in an N₂ atmosphere or an N₂/H₂ atmosphere.

According to an embodiment of the method, the heating is carried out under a pressure of between and including 1 bar and 100 bar, in particular between and including 5 bar and 50 bar, for example, between and including 10 bar and 30 bar.

According to an embodiment of the method, the reactant mixture is heated for a time of between and including 1 hour and 12 hours, in particular of between and including 2 hours and 10 hours, for example between and including 3 hours and 7 hours.

A radiation emitting component with a phosphor is further specified. In at least one example, the phosphor described above is suitable and intended for use in a radiation emitting component described herein. Features and embodiments described with the phosphor and/or the method also apply to the radiation emitting component and vice versa.

According to an embodiment, the radiation emitting component comprises a semiconductor chip which, during operation, emits electromagnetic radiation of a first wavelength range and a conversion element with a phosphor described herein which converts electromagnetic radiation of the first wavelength range into electromagnetic radiation of a second wavelength range which is at least partially different from the first wavelength range. In particular, the radiation emitting component emits a mixed light, for example, white mixed light, comprising the electromagnetic radiation of the first wavelength range and the second wavelength range.

Advantageously, the radiation emitting component comprises a higher color rendering index due to the phosphor described herein. Furthermore, the radiation emitting component can be used in human centric lighting.

### BRIEF DESCRIPTION OF THE DRAWINGS

Further advantageous embodiments, configurations and developments of the phosphor, the method for producing a phosphor and the radiation emitting component are shown in the following exemplary embodiments illustrated with the figures.

Elements that are identical, similar or have the same effect are marked with the same reference signs in the figures. The figures and the proportions of the elements shown in the figures are not to be regarded as true to scale. Rather, individual elements, in particular layer thicknesses, may be shown in exaggerated size for better visualization and/or understanding.

FIG. 11 shows a schematic representation of a phosphor according to an exemplary embodiment.

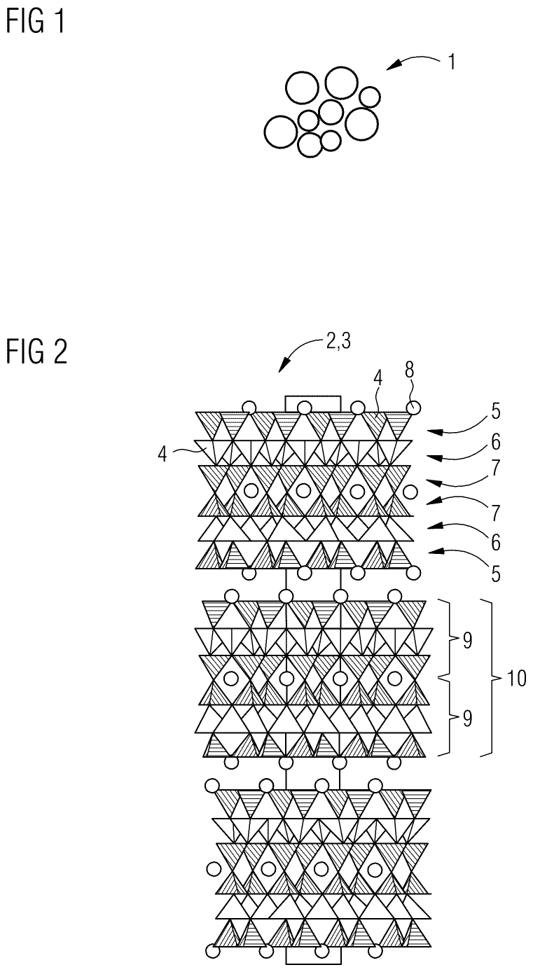

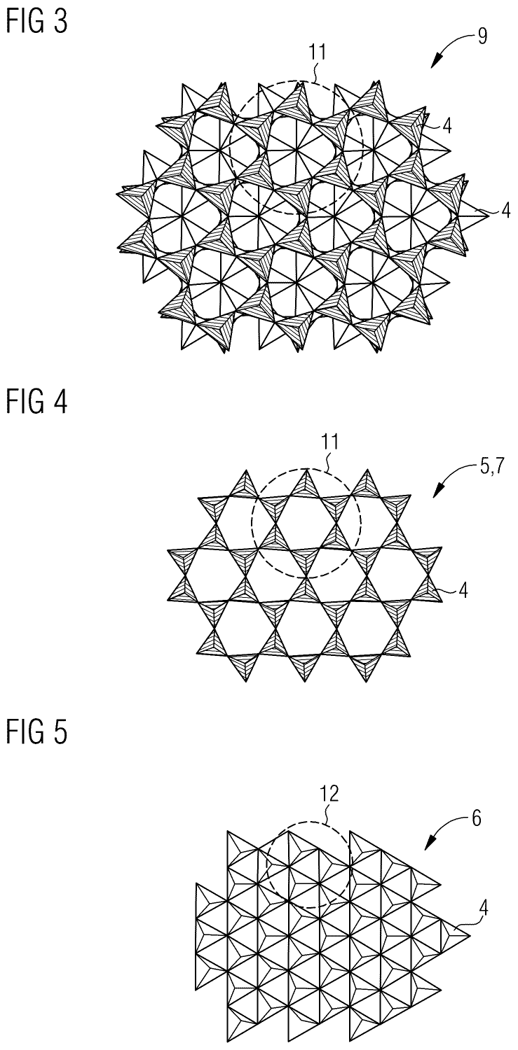

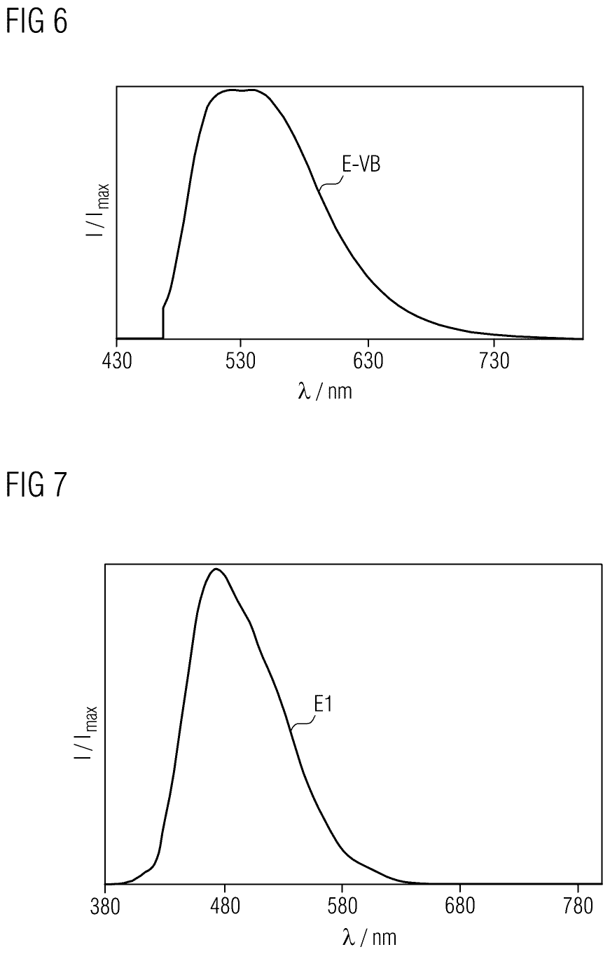

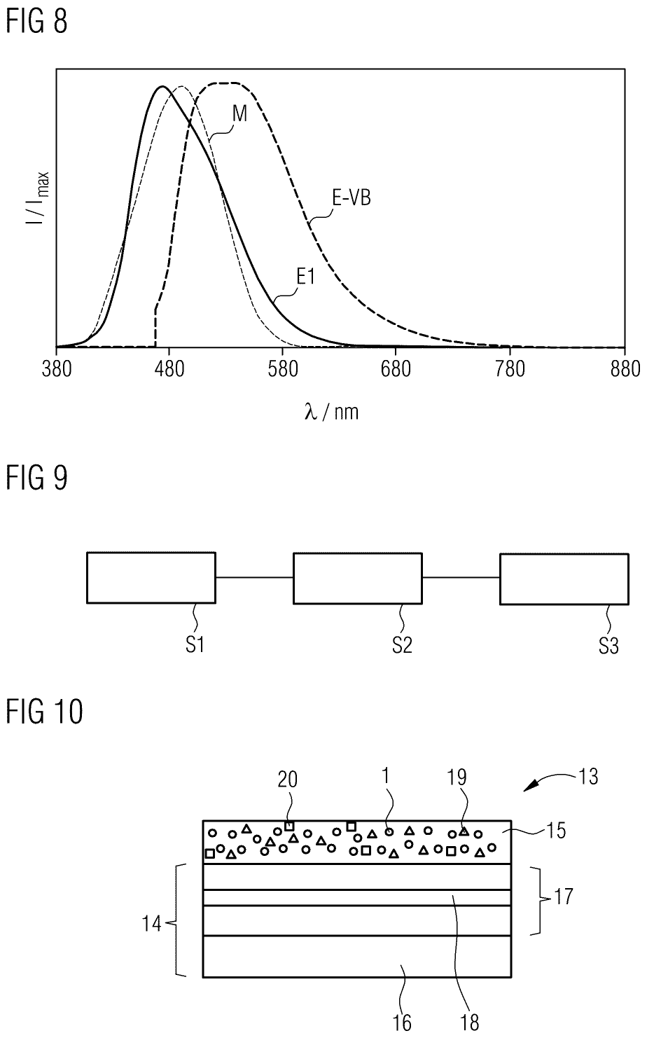

FIGS. 2 to 5 show schematic sections of a crystal structure of a host lattice of a phosphor according to an exemplary embodiment.

FIGS. 6 to 8 show emission spectra of a phosphor according to an exemplary embodiment and a phosphor according to a comparative example.

FIG. 9 schematically shows various steps of a method for producing a phosphor according to an exemplary embodiment.

FIG. 10 shows a radiation emitting component according to an exemplary embodiment.

### DESCRIPTION

The phosphor 1 according to FIG. 1 has the molecular formula EA₃₋ₓREₓD_{2+y}E_{12-y}N_{20-z}O_{z}:M, wherein EA is an element or a combination of elements from the group of divalent elements, RE is a rare earth element, D is an element or a combination of elements from the group of trivalent elements, E is an element or a combination of elements from the group of tetravalent elements, M is an activator element or a combination of activator elements, 0≤x≤3, 0≤y≤12 and z=y−x, wherein z≥0. In particular, the phosphor comprises the molecular formula Ba₃₋ₓLaₓAl₂₊ₓSi₁₂₋ₓN₂₀:Ce³⁺. The phosphor 1 is present in the form of particles which comprise a particle size of between and including 500 nanometers and 100 micrometers, for example.

FIG. 2 shows a section of a crystal structure 2 of a host lattice 3 of a phosphor 1. The phosphor 1 comprises the molecular formula Ba₃₋ₓLaₓAl₂₊ₓSi₁₂₋ₓN₂₀:Ce³⁺. The crystal structure is shown from the direction of the crystallographic b-axis. As the electron densities of La and Ba as well as Si and Al are very similar, it is not possible to reliably distinguish between these atoms using X-ray diffraction. Therefore, no exact value for x can be specified. However, x=1.5 can be estimated from the composition of the reactants during the method for producing the phosphor. Crystallographic data for Ba₃₋ₓLaₓAl₂₊ₓSi₁₂₋ₓN₂₀:Ce³⁺ are summarized in Table 1. Table 2 shows crystallographic location parameters of Ba₃₋ₓLaₓAl₂₊ₓSi₁₂₋ₓN₂₀:Ce³⁺.

TABLE 1
Crystallographic data of Ba₃₋ₓLaₓAl₂₊ₓSi₁₂₋ₓN₂₀:Ce³⁺

| molecular formula | Ba₃₋ₓLaₓAl₂₊ₓSi₁₂₋ₓN₂₀:Ce³⁺ |
|---|---|
| Crystal system | Trigonal |
| space group | R3̅ |
| Grid parameters | |
| a/pm 539.20(4) | α/°90 |
| b/pm 539.20(4) | β/°90 |
| c/pm 5124.9(5) | γ/°120 |
| Volume V/nm³ | 1.2904(2) |
| Crystallographic density ρ/g cm⁻³ | 4.165 |
| T/K | 296 (2) |
| Diffractometer | Bruker D8 Quest |
| Radiation | Cu K_{α} (154.178 nm) |
| Measuring range | 2.5773° ≤ θ ≤ 70.0714° |
| Measured/independent reflexes | 10948/604 |
| Measured reciprocal space | −6 ≤ h ≤ 6; |
| | −6 ≤ k ≤ 6; |
| | −63 ≤ l ≤ 63 |
| Rₐₗₗ/wR_{ref} | 4.13%/10.24% |
| GooF | 1.168 |

TABLE 2
Crystallographic location parameters of Ba₃₋ₓLaₓAl₂₊ₓSi₁₂₋ₓN₂₀:Ce³⁺.

| | Atom | Wyckoff | | | | | |
|---|---|---|---|---|---|---|---|
| Name | type | location | x | Y | z | Occupation | Uᵢₛₒ |
| Ba/La01 | Ba/La | 6c | 1.0 | 1.0 | 0.64723(2) | 1 | 0.0259(3) Uₐₙᵢ |
| Ba/La02 | Ba/La | 3b | 0 | 0 | 0.5 | 1 | 0.0359(3) Uₐₙᵢ |
| Si01 | Si | 6c | 0.333333 | 0.666667 | 0.53206(6) | 1 | 0.0234(6) |
| Si02 | Si | 6c | 0.333333 | 0.666667 | 0.46757(6) | 1 | 0.0238(6) |
| Si03 | Si | 6c | 0.666667 | 0.333333 | 0.62492(6) | 1 | 0.0241(6) |
| Si04 | Si | 6c | 0.333333 | 0.666667 | 0.62719(6) | 1 | 0.0250(7) |
| Al01 | Al | 18f | 0.3275(4) | 0.9973(4) | 0.57883(3) | 1 | 0.0222(5) |
| NO1 | N | 6c | 0.333333 | 0.666667 | 0.49999(16) | 1 | 0.0196(18) |
| NO2 | N | 6c | 0.666667 | 0.333333 | 0.59053(17) | 1 | 0.024(2) |
| NO3 | N | 18f | 0.5290(12) | 0.5239(12) | 0.63802(10) | 1 | 0.0290(12) |
| NO4 | N | 6c | 0 | 0 | 0.58881(19) | 1 | 0.028(2) |
| NO5 | N | 18f | 0.4000(12) | 0.9987(12) | 0.54383(10) | 1 | 0.0262(12) |
| NO6 | N | 6c | 0.333333 | 0.666667 | 0.59222(17) | 1 | 0.028(2) |

The section of the crystal structure 2 of the host lattice 3 of the phosphor 1 shown in FIG. 2 comprises on all sides corner-linked AlN₄ tetrahedra 4 and on all sides corner-linked SiN₄ tetrahedra 4. As described above, it is not possible to reliably distinguish between the AlN₄ tetrahedra 4 and the SiN₄ tetrahedra 4 by X-ray diffraction. The AlN₄ and SiN₄ tetrahedra 4 form a first layer 5, a second layer 6 and a third layer 7. Three corners of the SiN₄ tetrahedra 4 and the AlN₄ tetrahedra 4 are used for linking within one of the layers 5, 6, 7, the fourth corner of the SiN₄ tetrahedra 4 and the AlN₄ tetrahedra 4 is used for linking between the layers 5, 6, 7. The fourth corner points in the direction of the crystallographic c-axis. The first layer 5, the second layer 6 and the third layer 7 are each extended along the crystallographic a- and b-axis.

The Ba atoms 8 and the La atoms 8 are arranged between the layers 5, 6, 7. Due to the similar electron density of Ba and La, their positions cannot be distinguished. The activator element Ce³⁺ occupies part of the positions of the Ba atoms 8 and the La atoms 8.

The first layer 5, the second layer 6, and the third layer 7 form a layer stack 9. A layer stack 9 together with a further, inversion-symmetrically arranged layer stack 9 forms a layer packet 10. A layer packet 10 comprises six layers 5, 6, 7, in particular two first layers 5, two second layers 6 and two third layers 7. In the layer packet 10, two layers 7 are linked via the corners of the SiN₄ and/or AlN₄ tetrahedra 4, which are not used for linking within the layer 7.

FIG. 3 shows a layer stack 9 from the direction of the crystallographic c-axis. The first layer 5 of the layer stack 9 comprises six-membered rings 11. A six-membered ring 11 comprises a total of six AlN₄ and/or SiN₄ tetrahedra 4. The third layer 7 of the layer stack 9 also comprises six-membered rings 11. For better visibility of the structure of the first layer 5 and the third layer 7, a section of a single one of these layers 5, 7 is shown in FIG. 4. In layer 5, 7, an AlN₄ and/or SiN₄ tetrahedron 4 is connected with three further AlN₄ and/or SiN₄ tetrahedrons 4.

The second layer 6 comprises three-membered rings 12, which are formed from a total of three AlN₄ and/or SiN₄ tetrahedra 4. A section of the second layer 6 is shown in FIG. 5. In the second layer 6, an AlN₄ and/or SiN₄ tetrahedron 4 is connected with six further AlN₄ and/or SiN₄ tetrahedra 4.

FIG. 6 shows an emission spectrum E-VB of a phosphor 1 according to a comparative example with the molecular formula Lu₃Al₅O₁₂:Ce³⁺. The emission spectrum E-VB is shown in a wavelength range of between and including 430 nanometers and 800 nanometers.

In FIG. 7 an emission spectrum E1 of a phosphor 1 according to the exemplary embodiment with the molecular formula Ba₃₋ₓLaₓAl₂₊ₓSi₁₂₋ₓN₂₀:Ce³⁺ is shown. The emission spectrum is shown in a wavelength range of between and including 380 nanometers and 800 nanometers. Spectral data of phosphor 1 with the molecular formula Ba₃₋ₓLaₓAl₂₊ₓSi₁₂₋ₓN₂₀:Ce³⁺ after excitation with electromagnetic radiation of a wavelength of about 408 nanometers are summarized in Table 3.

TABLE 3
Spectral data of Ba₃₋ₓLaₓAl₂₊ₓSi₁₂₋ₓN₂₀:Ce³⁺.

| | Ba₃₋ₓLaₓAl₂₊ₓSi₁₂₋ₓN₂₀:Ce³⁺⁺ |
|---|---|
| excitation wavelength | 408 nm |
| dominant wavelength λ_{dom} | 488 nm |
| peak wavelength λₘₐₓ | 474 nm |
| FWHM | 93 nm |

FIG. 8 shows the emission spectra E-VB and E1 as well as a melanopic curve M. The emission spectra E-VB and E1 as well as the melanopic curve M are shown in a wavelength range of between and including 380 nanometers and 880 nanometers. The emission spectrum E1 of phosphor 1 with the molecular formula Ba₃₋ₓLaₓAl₂₊ₓSi₁₂₋ₓN₂₀:Ce³⁺ comprises a significantly larger overlap with the melanopic curve M than the emission spectrum E-VB of the comparative example with the molecular formula Lu₃Al₅O₁₂:Ce³⁺. The larger overlap is also reflected in the comparison of the melanopic ELR and the relative melanopic ELR of Ba₃₋ₓLaₓAl₂₊ₓSi₁₂₋ₓN₂₀:Ce³⁺ and Lu₃Al₅O₁₂:Ce³⁺, which are shown in Table 4.

TABLE 4
Comparison of the melanopic ELR.

| | | Ba₃₋ₓLaₓAl₂₊ₓSi₁₂₋ₓN₂₀:Ce³⁺ |
|---|---|---|
| phosphor | Lu₃Al₅O₅₁₂:Ce³⁺ | (excitation at 408 nm) |
| melanopic ELR | 0.6572 | 1.9970 |
| relative melanopic | 100% | 304% |
| ELR | | |

In the exemplary embodiment of the method for producing a phosphor 1 shown in FIG. 9, reactants are provided in a method step S1. In the present case, the phosphor 1 has the molecular formula Ba₃₋ₓLaₓAl₂₊ₓSi₁₂₋ₓN₂₀:Ce³⁺. The reactants and their weights are summarized in Table 5.

TABLE 5
Weights for the synthesis of Ba₃₋ₓLaₓAl₂₊ₓSi₁₂₋ₓN₂₀:Ce³⁺.

| Exemplary | | | | | | |
|---|---|---|---|---|---|---|
| embodiment | x | CeO₂ | BaN_{0.94} | LaN | Si₃N₄ | AlN |
| 1 | 1.5 | 0.100 | 2.5804 | 2.6072 | 4.0095 | 0.7029 |
| | | g | g | g | g | g |
| 2 | 1.5 | 0.100 | 3.8172 | 3.8564 | 1.1865 | 1.0399 |
| | | g | g | g | g | g |

The reactants are mixed in a further method step S2 to form a reactant mixture. Mixing takes place, for example, in a hand mortar, a mortar mill, a ball mill or a multi-axis mixer. The reactant mixture is then transferred to a crucible, for example made of tungsten.

The reactant mixture is then heated in a method step S3 to around 1850° C. for 4 hours at 20 bar under an N₂ atmosphere or an atmosphere of an N₂/H₂ mixture (95/5%). After the reaction and cooling, the product is grinded. Grinding is carried out in a hand mortar, a mortar mill or a ball mill, for example.

The radiation emitting component 13 according to the exemplary embodiment of FIG. 10 comprises a semiconductor chip 14 which emits electromagnetic radiation of a first wavelength range during operation. The semiconductor chip 14 comprises a substrate 16 on which a semiconductor layer sequence 17 is epitaxially grown. The semiconductor layer sequence 17 comprises an active region 18. During operation of the radiation emitting component 13, the active region 18 generates electromagnetic radiation of the first wavelength range. In the present case, the semiconductor chip 14 emits electromagnetic radiation in the ultraviolet to blue wavelength range of the electromagnetic spectrum.

The radiation emitting component 13 further comprises a conversion element 15. The conversion element 14 is arranged on a side of the semiconductor layer sequence 17 that faces away from the substrate 16. In other words, the conversion element 15 is arranged downstream of the semiconductor chip 14. The conversion element 15 comprises a phosphor 1, for example Ba₃₋ₓLaₓAl₂₊ₓSi₁₂₋ₓN₂₀:Ce³⁺. In the present case, the conversion element 15 also comprises a further phosphor 19.

The phosphor 1 converts the electromagnetic radiation of the first wavelength range into electromagnetic radiation of a second wavelength range. The second wavelength range is at least partially different from the first wavelength range. The second phosphor 19 converts the electromagnetic radiation of the first wavelength range into electromagnetic radiation of a third wavelength range. The third wavelength range is at least partially different from the first wavelength range and/or the second wavelength range. For example, the second phosphor is a phosphor from the class of garnets, such as (Lu, Y, Yb, Gd, Tb)₃(Ga, Al, Si)₅O₁₂:Ce³⁺. In the present case, the third wavelength range is the green to orange wavelength range of the electromagnetic spectrum.

It is further possible that the conversion element 15 comprises a third phosphor 20 which converts electromagnetic radiation of the first wavelength range into electromagnetic radiation of a fourth wavelength range which is at least partially different from the first wavelength range, the second wavelength range and/or the third wavelength range. In the present case, the fourth wavelength range is the red wavelength range of the electromagnetic spectrum. For example, the third phosphor 20 is a red-emitting nitride phosphor, such as (Ca, Ba, Sr)₂(Si, Al)₅(N, O)₈:Eu²⁺ or (Sr, Ca)AlSiN₃:Eu²⁺.

In the present case, the radiation emitting component 13 emits a mixed light that comprises the electromagnetic radiation of the first wavelength range, the second wavelength range and the third wavelength range. In the present case, the mixed light is white light.

The features and exemplary embodiments described in connection with the figures may be combined with each other in accordance with further exemplary embodiments, even if not all combinations are explicitly described. Furthermore, the exemplary embodiments described in connection with the figures may alternatively or additionally comprise further features as described in the general part.

The present disclosure is not limited to the exemplary embodiments by the description thereof. Rather, the present disclosure includes any new feature as well as any combination of features, which includes in particular any combination of features in the patent claims, even if this feature or combination itself is not explicitly specified in the patent claims or exemplary embodiments.

### LIST OF REFERENCE SIGNS

1 phosphor
2 crystal structure
3 Host lattice
4 tetrahedron
5, 6, 7 layers
8 Ba/La atom
9 layer stack
10 layer packet
11 six-membered ring
12 three-membered ring
13 radiation emitting component
14 semiconductor chip
15 conversion element
16 substrate
17 semiconductor layer sequence
18 active region
19 second phosphor
20 third phosphor
S1, S2, S3 method steps
E-VB emission spectrum of Lu₃Al₅O₁₂:Ce³⁺
E1 emission spectrum of Ba₃₋ₓLaₓAl₂₊ₓSi₁₂₋ₓN₂₀:Ce³⁺
M melanopic curve

What is claimed is:

1. A phosphor with a molecular formula EA₃₋ₓREₓD_{2+y}E_{12-y}N_{20-z}O_{z}:M, wherein
EA is an element or a combination of elements from the group of divalent elements,
RE is a rare earth element,
D is an element or a combination of elements from the group of trivalent elements,
E is an element or a combination of elements from the group of tetravalent elements,
M is an activator element or a combination of activator elements, and
0≤x≤3, 0≤y≤12 and z=y−x, wherein z≥0.

2. The phosphor according to claim 1, wherein
EA is an element or a combination of elements from the group formed by Ca, Sr and Ba, and/or
D is an element or a combination of elements from the group formed by Al and Ga, and/or
E is Si, and/or
M is an element or a combination of elements from the group formed by Ce and Eu.

3. The phosphor according to claim 1, wherein the phosphor (1) comprises the molecular formula Ba₃₋ₓLaₓAl_{2+y}Si_{12-y}N_{20-z}O_{z}:Ce³⁺.

4. The Phosphor according to claim 1, wherein the phosphor, after excitation with electromagnetic radiation in the ultraviolet to blue wavelength range, emits electromagnetic radiation with an emission spectrum comprising an emission peak with an emission maximum in the cyan wavelength range.

5. The phosphor according to claim 1, wherein the emission peak comprises a full-width at half maximum in the region of between and including 80 nanometers and 110 nanometers.

6. The phosphor according to claim 1, wherein an electromagnetic radiation emitted by the phosphor comprises a dominant wavelength λ_{dom} in the region of between and including 470 nanometers and 500 nanometers.

7. The phosphor according to claim 1, wherein a host lattice of the phosphor crystallizes in a trigonal space group.

8. The phosphor according to claim 1, wherein a crystal structure of the host lattice of the phosphor comprises layers with on all side corner-linked D(N,O)₄ tetrahedra and/or E(N,O)₄ tetrahedra.

9. A method for producing a phosphor with the molecular formula EA₃₋ₓREₓD_{2+y}E_{12-y}N_{20-z}O_{z}:M, wherein
EA is an element or a combination of elements from the group of divalent elements,
RE is a rare earth element,
D is an element or a combination of elements from the group of trivalent elements,
E is an element or a combination of elements from the group of tetravalent elements,
M is an activator element or a combination of activator elements, and
0<x≤3, 0≤y≤12 and z=y−x, where z≥0,
the method comprising:
providing reactants,
mixing the reactants to form a reactant mixture, and
heating the reactant mixture.

10. A radiation emitting component comprising:
a semiconductor chip which emits electromagnetic radiation of a first wavelength range during operation, and
a conversion element with a phosphor according to claim 1, which converts electromagnetic radiation of the first wavelength range into electromagnetic radiation of a second wavelength range which is at least partially different from the first wavelength range.
